(19) United States
(12) Patent Application Publication
(10) Pub. No.: US 2011/0030758 A1
(43) Pub. Date: Feb. 10, 2011

(54) PHOTOVOLTAIC DEVICE AND MANUFACTURING METHOD THEREOF

(75) Inventor: Tatsuya KIRIYAMA, Hashima-gun (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/851,051

(22) Filed: Aug. 5, 2010

(30) Foreign Application Priority Data
Aug. 7, 2009 (JP) 2009-185109
Sep. 29, 2009 (JP) 2009-224378

(51) Int. Cl. H01L 31/042; H01L 21/66; H01L 21/78; H01L 31/18

(52) U.S. Cl. 136/244; 438/12; 438/68; 257/E21.531; 257/E21.599

(57) ABSTRACT

To manufacture a photovoltaic device through a first step of sequentially stacking a transparent electrode, a photovoltaic layer, and a rear surface electrode to thereby form a structure in which photovoltaic cells are serially connected, a second step of measuring characteristics of the photovoltaic cell; and a third step of removing, according to a result of measurement, the transparent electrode, the photovoltaic layer, and the rear surface electrode along the serial connection direction, to thereby divide the serially connected photovoltaic cells into a plurality of regions.

### CROSS-REFERENCE TO RELATED APPLICATIONS

The entire disclosure of Japanese Patent Applications No. 2009-185109 filed on Aug. 7, 2009 and No. 2009-224378 filed on Sep. 29, 2009, including specifications, claims, drawings, and abstract, are incorporated herein by reference in its entirety.

### BACKGROUND OF THE INVENTION

1. Field of the Invention

The present invention relates to a photovoltaic device and a manufacturing method thereof.

2. Description of the Related Art

There is known a photovoltaic device using polycrystalline, microcrystal, or amorphous silicon. In particular, photovoltaic devices having a structure in which microcrystal or amorphous silicon thin films are stacked are attracting attention in terms of resource consumption, cost reduction, and improved efficiency.

FIG. 9 is a schematic cross sectional view of a basic structure of a photovoltaic device 100. The photovoltaic device 100 generally has a structure in which a transparent electrode 12, a photovoltaic layer 14, and a rear surface electrode 16 are placed one on the other on a transparent substrate 10 made of a material such as glass or the like, for generating electric power with light incident on the transparent substrate 10. A manufacturing method for serially mounting such a photovoltaic device and a patterning device therefore are disclosed.

FIG. 10A to FIG. 10F show steps of manufacturing a conventional photovoltaic device 100. FIG. 10A to FIG. 10F schematically show plan views and cross sectional views relating to the respective steps of manufacturing the photovoltaic device 100. The cross sectional views are those along line A-A and those along line B-B in the plan views.

At S10, as shown in FIG. 10A, a slit S1 is formed by laser processing to divide the transparent electrode 12 formed on the transparent substrate 10, and a slit S2 is formed in the direction orthogonal to the slit S1.

At S12, as shown in FIG. 10B, the photovoltaic layer 14 is formed covering the transparent electrode 12. Note that an amorphous silicon (a-Si) photovoltaic layer, a microcrystal (pc-Si) photovoltaic layer, or a tandem structure including these two can be mentioned as the photovoltaic layer 14.

At S14, as shown in FIG. 10C, a slit S3 is formed by laser processing at a position in the vicinity of, but not overlapping, the slit S1 to divide the photovoltaic layer 14 along the direction of the slit S1.

At S16, as shown in FIG. 10D, a rear surface electrode 16 is formed covering the photovoltaic layer 14.

At S18, as shown in FIG. 10E, a slit S4 is formed by laser processing at a position in the vicinity of, but not overlapping, the slit S3 on the opposite side from the slit S1 relative to the slit S3, to divide the photovoltaic layer 14 and the rear surface electrode 16 along the directions of the slits S1 and S3. With the above, a structure in which a plurality of photovoltaic cells are serially connected along the direction of the slit S2 is obtained.

At S20, as shown in FIG. 10F, a slit S5 is formed in the slit S2 by laser processing to divide the photovoltaic layer 14 and the rear surface electrode 16. With the above, the photovoltaic cells adjacent to each other along the direction of the slit S1 are electrically separated from each other, and accordingly, this results in a structure in which photovoltaic cell groups, each including a plurality of serially connected photovoltaic cells, are arranged in parallel. The photovoltaic cell groups are finally connected in parallel, whereby the photovoltaic device 100 is formed.

Here, as shown in FIG. 11, it is often the case that a defect which causes short-circuit between the substrate 10 and the rear surface electrode 16 is undesirably formed in a plane of the photovoltaic device. Note that such a defect is indicated by the black circle in FIG. 11.

In a conventional photovoltaic device, as shown in FIG. 11, the slits S2 and S5 are formed with the same interval, whereby a structure in which a plurality of groups of serially connected photovoltaic cells are arranged in parallel is obtained. With a defect present in a photovoltaic cell, power generation is not achieved in the region of the photovoltaic cell with the defect (hatched in the diagram). That is, with a structure in which the groups of photovoltaic cells are arranged in parallel at the same interval, power generation by the photovoltaic cells corresponding to the defected column is wasted. This causes drop in power generation efficiency of the photovoltaic device as a whole.

Further, according to a conventional method for manufacturing a photovoltaic device, the slit S2 is formed by laser processing to divide the transparent electrode 12 prior to sequential stacking of the photovoltaic layer 14 and the rear surface electrode 16 on the transparent substrate 10 including the slit S2. Thereafter, the slit S5 is formed by laser processing so as to overlap the slit S2 to electrically separate the adjacent photovoltaic cells. That is, the slits S2 and S5 need to be overlapped for electrical separation. Therefore, the position of a slit to divide the photovoltaic cells is not allowed to be freely decided at the step of forming the slit S2 and subsequent steps. That is, according to a conventional technique, there is a problem that the order of manufacturing steps is not reversible, that is, there is little freedom allowed in manufacturing.

### SUMMARY OF THE INVENTION

According to one aspect of the present invention, there is provided a method for manufacturing a photovoltaic device, comprising a first step of sequentially stacking a first electrode, a photovoltaic layer, and a second electrode to serially connect a plurality of photovoltaic elements; a second step of measuring characteristics of the photovoltaic element; and a third step of removing, according to a result of measurement, the first electrode, the photovoltaic layer, and the second electrode along a direction in which the photovoltaic elements are serially connected to thereby divide the plurality of photovoltaic elements serially connected into a plurality of regions.

According to another aspect of the present invention, there is provided a photovoltaic device in which a plurality of photovoltaic elements where a first electrode, a photovoltaic layer, and a second electrode are sequentially stacked are serially connected, wherein the first electrode, the photovoltaic layer, and the second electrode are removed along a direction in which the photovoltaic elements are serially connected, to thereby divide the plurality of photovoltaic elements serially connected into a plurality of regions having different areas.

According to still another aspect of the present invention, there is provided a method of manufacturing a photovoltaic device, comprising a first step of sequentially stacking a first electrode, a photovoltaic layer, and a second electrode to thereby form a photovoltaic element; a second step of removing the second electrode and the photovoltaic layer to thereby form a first slit; a third step of removing the first electrode in a region overlapping the first slit to thereby form a second slit to thereby divide the photovoltaic element into a plurality of regions.

According to still another aspect of the present invention, there is provided a method of manufacturing a photovoltaic device, comprising a first step of sequentially stacking a first electrode, a photovoltaic layer, and a second electrode to thereby form a photovoltaic element; a second step of removing the first electrode, the photovoltaic layer, and the second electrode to thereby form a third slit to thereby divide the photovoltaic element into a plurality of regions; and a third step of removing the second electrode and the photovoltaic layer in a region including the third slit to thereby form a fourth slit.

### BRIEF DESCRIPTION OF THE DRAWINGS

A preferred embodiment of the present invention will be described in further detail based on the following drawings, wherein:

FIG. 1A to 1G are plan views and cross sectional views showing a process of manufacturing a photovoltaic device in an embodiment of the present invention;

FIG. 2 is a flowchart of a process of manufacturing a photovoltaic device in the embodiment of the present invention;

FIG. 3 is a plan view showing a result of detecting the position of a defect in the embodiment of present invention;

FIG. 4 is a plan view showing a result of detecting the position of a defect in the embodiment of present invention;

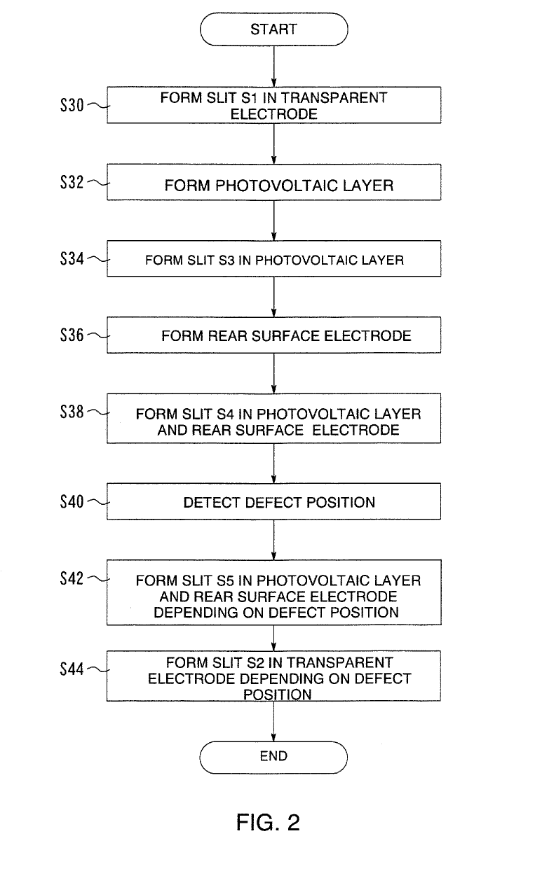

FIG. 5 is a cross sectional view explaining formation of slits S2 and S5 in the embodiment of the present invention;

FIG. 6 is a plan view explaining formation of slits S2 and S5 in the embodiment of the present invention;

FIG. 7 is a plan view explaining formation of slits S2 and S5 in the embodiment of the present invention;

FIG. 8 is a flowchart of steps of manufacturing a photovoltaic device in the embodiment of the present invention;

FIG. 9 is a cross sectional view showing a basic structure of a photovoltaic device;

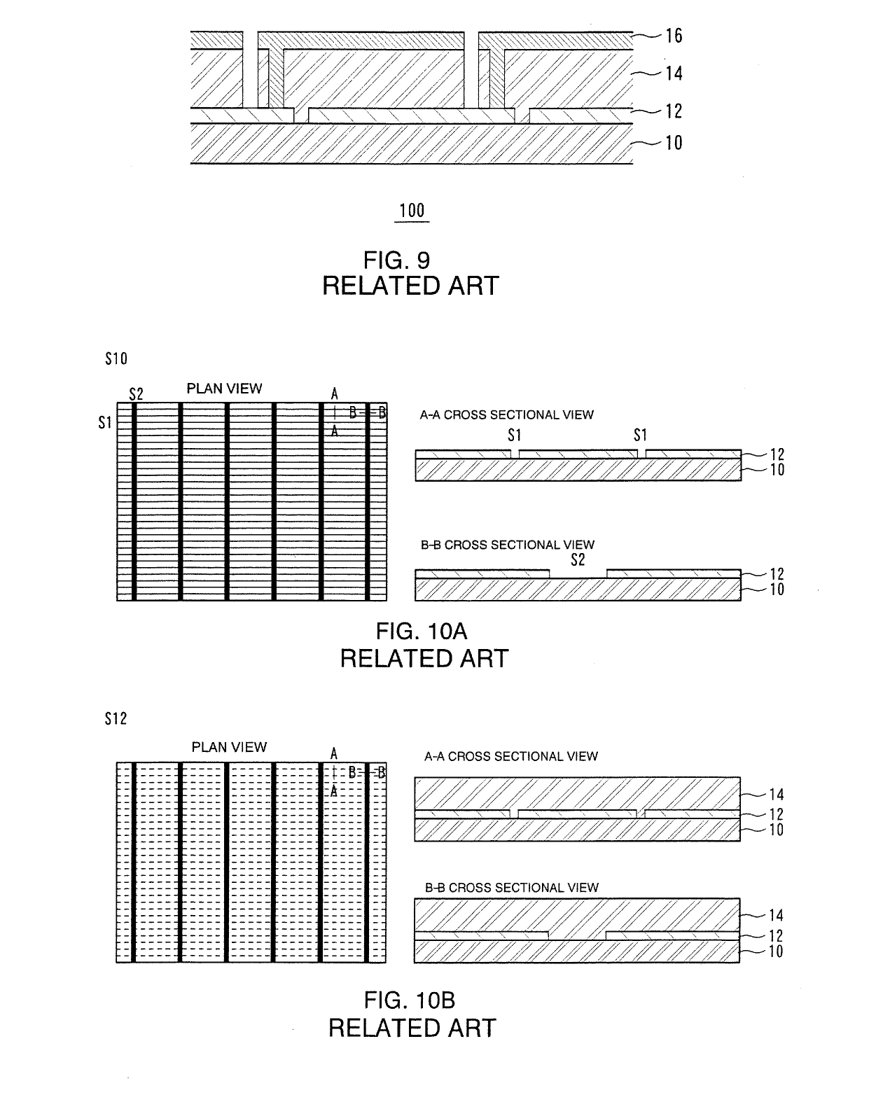

FIG. 10A to 10F are plan views and cross sectional views showing a process of manufacturing a conventional photovoltaic device;

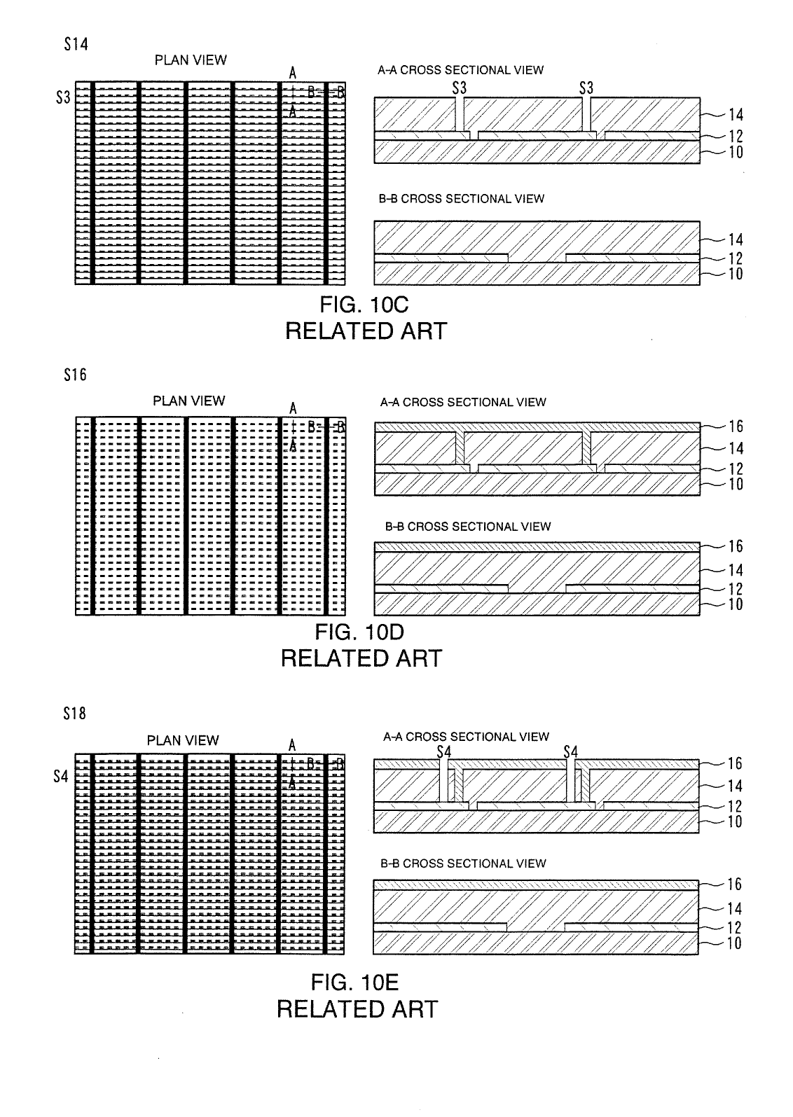

FIG. 11 is a plan view showing a conventional photovoltaic device.

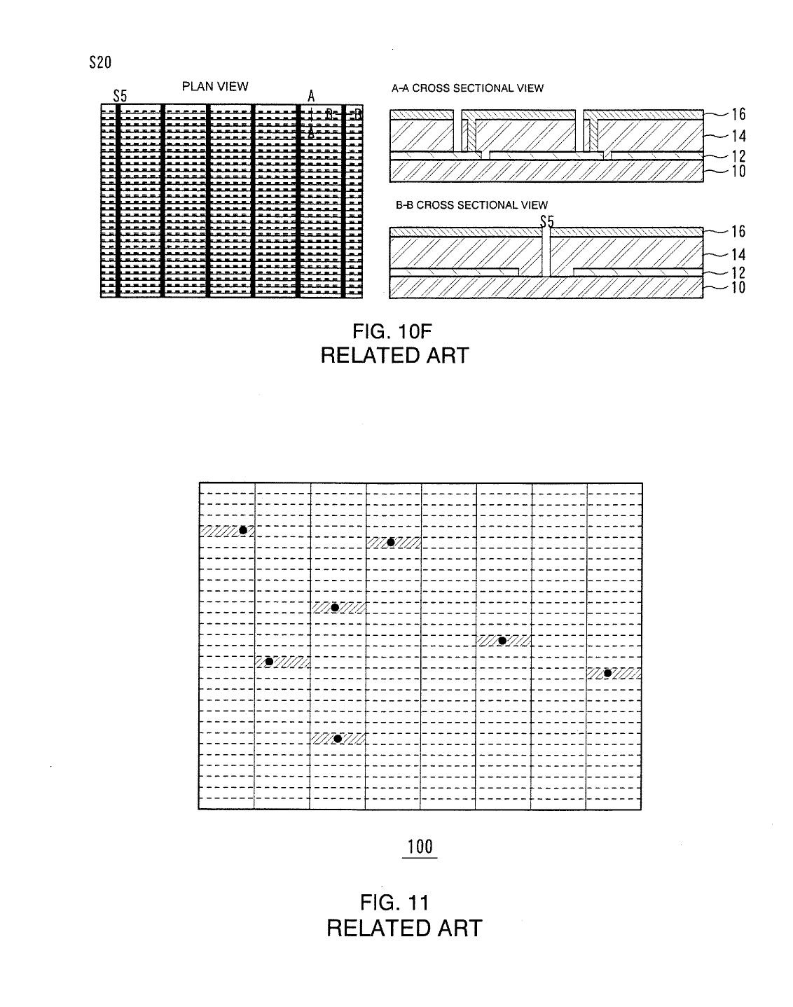

### DESCRIPTION OF THE PREFERRED EMBODIMENTS

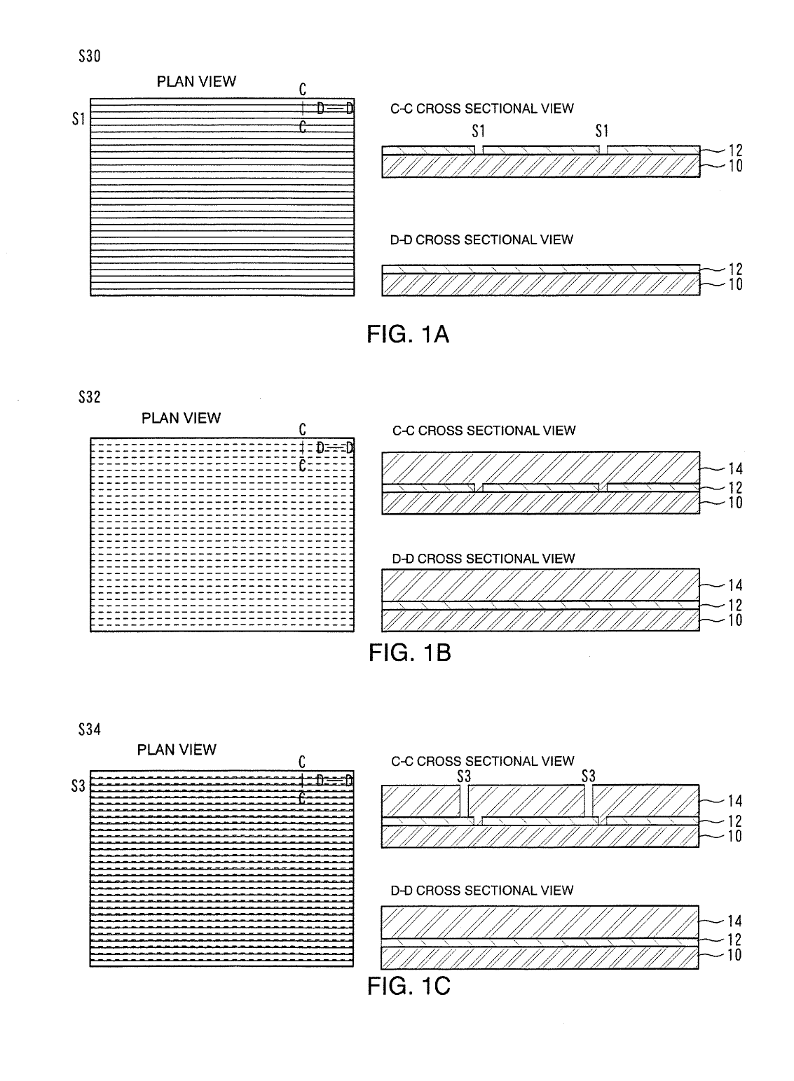

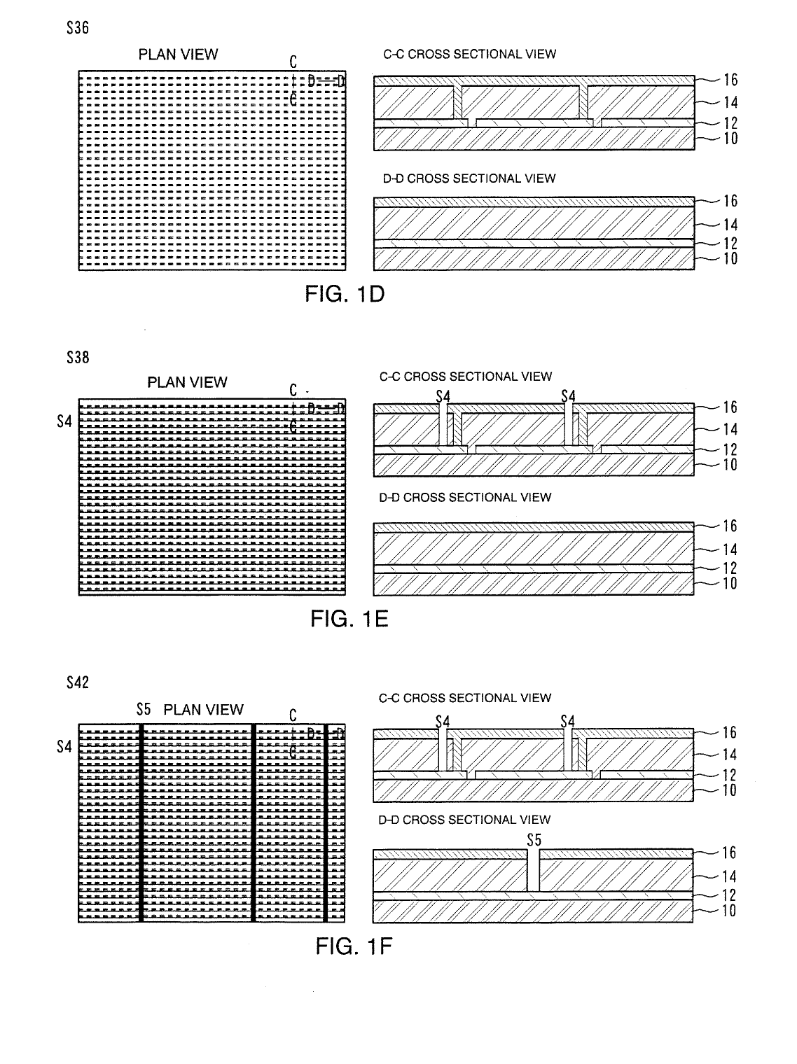

FIGS. 1A to 1G and FIG. 2 show steps of manufacturing a photovoltaic device 200 according to this embodiment. Specifically, FIGS. 1A to 1G schematically show plan views and cross sectional views relating to the respective steps of manufacturing the photovoltaic device 200. FIG. 2 is a flowchart of a process of manufacturing the photovoltaic device 200. The cross sectional views in FIGS. 1A to 1G are those along line C-C and those along line D-D in the plan views.

At S30, as shown in FIG. 1A, a slit S1 (the left-right direction in diagram drawing) is formed by laser processing to divide the transparent electrode 12 formed on the transparent substrate 10. The transparent substrate 10 is made of material such as, e.g., glass, plastic, or the like, which passes light having a wavelength which is used in photovoltaic in a photovoltaic device. The transparent electrode 12 can be made of transparent electrically conductive oxide (TCO) which is formed by doping tin (Sn), antimony (Sb), fluorine (F), aluminum (Al), and so forth, into stannous oxide (SnO₂), zinc oxide (ZnO), indium tin oxide (ITO), and so forth.

As a laser device used to form the slit S1, preferably, a YAG laser with a wavelength 1064 nm is used. A laser beam with power adjusted is irradiated from a laser device located on the transparent electrode 12 side and continuously run in the direction of the slit S1, whereby the slit S1 can be formed. Note that the laser beam for forming the slit S1 may be irradiated from the transparent substrate 10 side, instead.

Further, because many slits S1 need to be formed to serially mount many photovoltaic cells, preferably, a multiple irradiation type laser device having laser beam irradiating outlets arranged with the same interval in the direction orthogonal to the slit S1 is used. For example, preferably, a laser device having two to five laser beam irradiating outlets arranged is used. With use of such a laser device, many slits S1 can be formed at a high speed for serially mounting many photovoltaic cells.

At S32, as shown in FIG. 1B, a photovoltaic layer 14 is formed covering the transparent electrode 12 and the slit S1. Although not being particularly limited, the photovoltaic layer 14 may include, e.g., an amorphous silicon (a-Si) photovoltaic layer, a microcrystal (μc-Si) photovoltaic layer, or a tandem structure of these two. The photovoltaic layer 14 can be formed using plasma CVD or the like.

At S34, as shown in FIG. 1C, the slit S3 is formed in laser processing to divide the photovoltaic layer 14. Specifically, the slit S3 is formed at a position in the vicinity of, but not overlapping, the slit S1 along the direction of the slit S1 so as to have a depth reaching the surface of the transparent electrode 12.

As a laser device used to form the slit S3, preferably, a YAG laser with a wavelength 532 nm (second harmonic wave) is used. A laser beam with power adjusted is irradiated from a laser device located on the transparent electrode 10 side and continuously run in the direction of the slit 51, whereby the slit S3 can be formed.

At S36, as shown in FIG. 1D, the rear surface electrode 16 is formed covering the photovoltaic layer 14 and the slit S3. Preferably, the rear surface electrode 16 is made of reflective metal. Alternatively, preferably, the rear surface electrode 16 may have a stacked structure including reflective metal and transparent electrically conductive oxide (TCO). As a metal electrode, silver (Ag), aluminum (Al), and so forth can be used. As a transparent electrically conductive oxide film (TCO), stannous oxide (SnO₂), zinc oxide (ZnO), indium tin oxide (ITO), and so forth can be used.

At S38, as shown in FIG. 1E, a slit S4 is formed by laser processing to divide the photovoltaic layer 14 and the rear surface electrode 16. The slit S4 is formed at a position in the vicinity of, but not overlapping, the slit S3 on the opposite side from the slit S1 relative to the slit S3 so as to divide the photovoltaic layer 14 and the rear surface electrode 16 along the directions of the slits S1 and S3 and so as to have a depth reaching the surface of the transparent electrode 12. With the above, a structure in which a plurality of photovoltaic cells are serially connected in the direction of the slit S2 is obtained.

As a laser device used to form the slit S4, preferably, a YAG laser with a wavelength 532 nm (second harmonic wave) is used. A laser beam with power adjusted is irradiated from a laser device located on the transparent electrode 10 side and run in the direction of the slit S1, whereby the slit S4 can be formed.

At S40, a defect included in a photovoltaic cell formed on the transparent substrate 10 is detected. Note that detection of a defect in this embodiment means specification of the position in a plane, of any cause which either directly or indirectly deteriorates the characteristics of a photovoltaic cell formed on the transparent substrate 10.

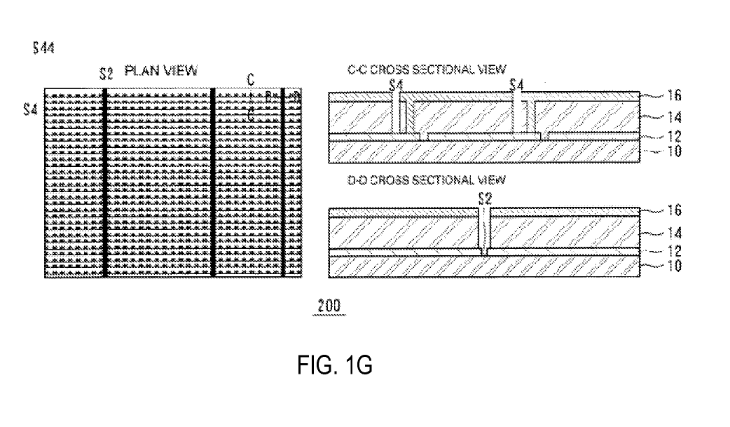

For example, preferably, the defect detection method disclosed in Japanese Patent No. 3098950 can be employed. According to this detection method, reverse bias is applied to the photovoltaic cell; infrared irradiated from the photovoltaic cell is detected using a photovoltaic device, such as a CCD, a CMOS, or the like; and the detected infrared strength is compared with a reference value to specify the position, in a plane, of a defect included in the photovoltaic device. With this method employed, it is possible to specify the coordinates (an absolute position) of a defect (indicated by the black circle in the diagram) in a plane of the photovoltaic device, as shown in the plan view in FIG. 3.

Alternatively, electrical characteristic may be measured to indirectly specify the position of a defect. For example, power generation characteristics (open-circuit voltage, short-circuit current, fill factor, power generation efficiency, and so forth) per unit area are measured for each group of the photovoltaic cells serially connected along the slit S2 to determine, when a measured result lower than the reference power generation characteristic is obtained, that a cell with a defect is included in that group of serially connected photovoltaic cells. Note that when such measurement is employed, the photovoltaic cells maybe divided in advance in parallel with a desired interval, using a method similar to that employed at steps S42 and S44 to be described later. In this case, it is possible to specify a column (hatched in the diagram) of serially connected photovoltaic cells which include a photovoltaic cell with a defect (indicated by the black circle in the diagram), though the absolute position of the defect in the column cannot be specified.

At S42, as shown in FIG. 1F, a slit S5 is formed (in the up-down direction in the diagram) by laser processing to divide the photovoltaic layer 14 and the rear surface electrode 16. That is, the slit S5 is formed in the direction orthogonal to the slit S1 so as to divide the photovoltaic layer 14 and the rear surface electrode 16 so that the serially connected photovoltaic cells are divided in parallel, and so as to have a depth reaching the surface of the transparent electrode 12.

Using a YAG laser with a wavelength 532 nm (second harmonic wave), a laser beam with power adjusted is irradiated from a laser device located on the transparent electrode 10 side so as to be focused in the boundary between the transparent electrode 12 and the photovoltaic layer 14 and run in a desired direction, whereby the slit S5 can be formed.

At S44, as shown in FIG. 1G, a slit S2 is formed by laser processing to divide the transparent electrode 12 formed on the transparent substrate 10. The slit S2 is formed overlapping the slit S5. With the slits S5 and S2, the photovoltaic cells adjacent to each other in the direction of the slit 51 are electrically separated.

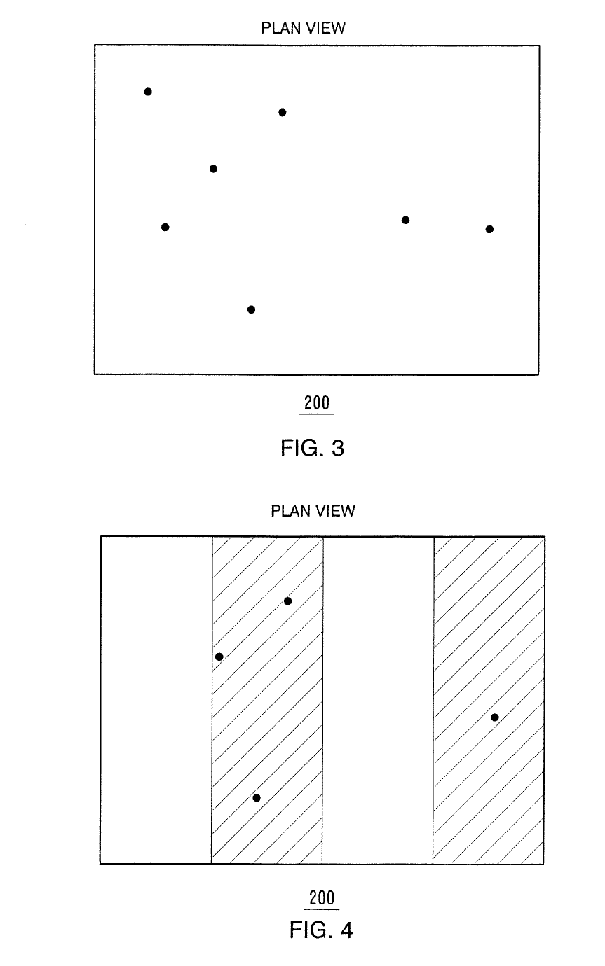

In this embodiment, as shown in the enlarged cross sectional view in FIG. 5, the laser beam width and irradiation position are adjusted when forming the slit S2 such that the full width L2 of the slit S2 is defined smaller than the full width L1 of the slit S5.

As a laser device used to form the slit S2, preferably, a YAG laser with a wavelength 1064 nm is used. A laser beam with power adjusted is irradiated from a laser device located on the transparent electrode 12 side so as to be focused on the surface of the transparent electrode 12, whereby the slit S2 can be formed. Note that the laser beam used to make the slit S2 may be irradiated from the transparent substrate 10 side, instead.

As described above, in this embodiment, it is possible to freely divide the photovoltaic cells after formation thereof by stacking the transparent electrode 12, the photovoltaic layer 14, and the rear surface electrode 16 one on the other on the substrate 10. Here, according to a conventional method, it is necessary to form the slit S2 to divide the transparent electrode 12, before forming the photovoltaic layer 14. That is, the position to divide the photovoltaic cells must be decided before completion of the photovoltaic cells. In other words, it is not possible to divide the photovoltaic cells into desired regions after completely forming the photovoltaic cells by stacking the transparent electrode 12, the photovoltaic layer 14, and the rear surface electrode 16 on the substrate 10. Meanwhile, in this embodiment, it is possible to divide the photovoltaic cells into desired regions after completely forming the photovoltaic cells. Accordingly, it is possible to make a structure including a plurality of photovoltaic cells, that is, to increase freedom in manufacturing.

Note that the slits S2 and S5 can be formed at a position determined depending on the position of a defect, specified at S40. That is, the slits S2 and S5 can be formed so as to separate the photovoltaic cell including the defect, specified at S40, from the photovoltaic cells in other regions.

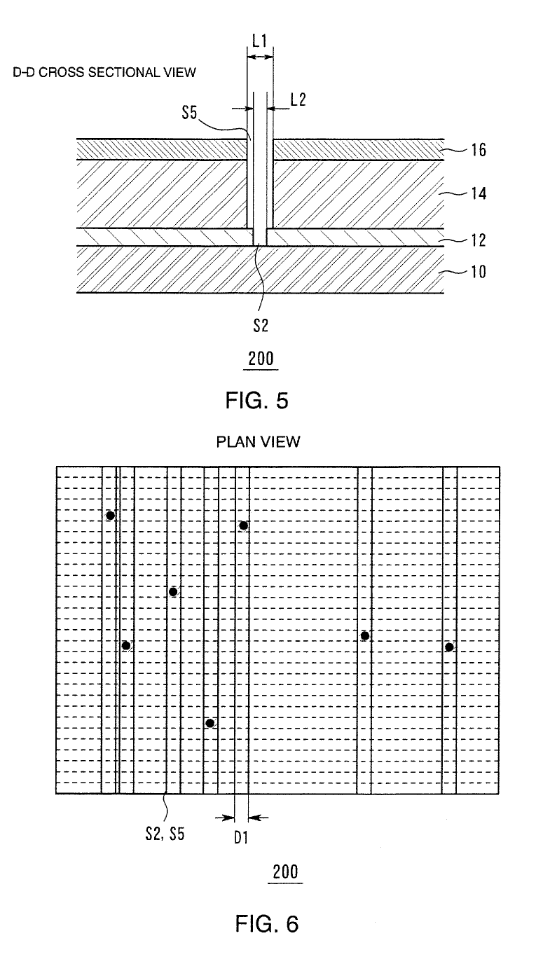

For example, in a case where the absolute position of a defect in a plane of a photovoltaic device can be specified, such as in the above described case using infrared, the slits S2 and S5 are formed such that a defect is included in a photovoltaic cell having a width D1 sandwiched by the slits S2 and S5, as shown in the plan view in FIG. 6. The width D1 is determined depending on the size of the region affected by the defect, and is preferably as narrow as possible. Alternatively, the slits S2 and S5 may be formed overlapping the position of a defect.

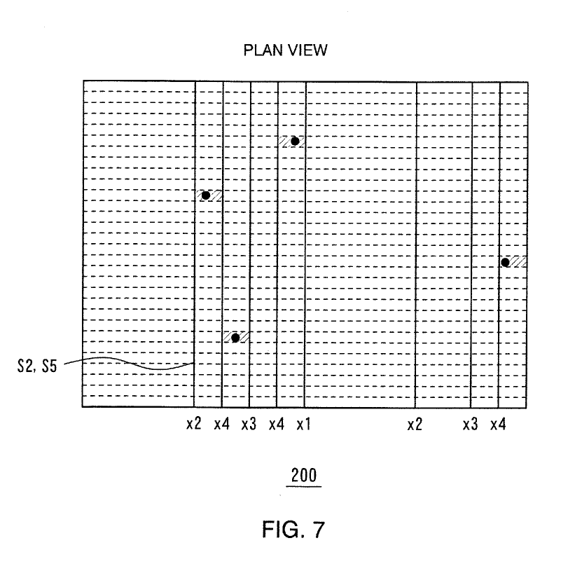

Meanwhile, in a case where the absolute position of a defect in a plane of a photovoltaic device cannot be specified, such as in the case using the above described electrical measurement method, the slits S2 and S5 are formed by repetitively carrying out a process of halving a photovoltaic cell column including a defect at the center thereof, as shown in the plan view in FIG. 7 . For example, in FIG. 7, the photovoltaic device is halved along the line xl, and thereafter, a measured result is compared with a reference power generation characteristic at S40 to specify a column with a defect . Further, the halved column is again halved along the line x2, and thereafter, a measured result is compared with a reference power generation characteristic at S40 to specify a column including more of a defect. Further, the halved column is yet again halved along the line x3.

As the processes at S40 to S44 are sequentially repeated in this manner, the width of the column of serially connected photovoltaic cells including a defect can be gradually narrowed down. With the above, the defect is resultantly included in any of the divided columns. The column of photovoltaic cells including none or a smaller portion of a defect and the column of photovoltaic cells including more of a defect are electrically separated.

Note that although a measured result is compared with a reference power generation characteristic to specify a column including a defect in the above, measured results of power generation characteristics of the columns having substantially identical widths and areas including the same number of serially connected photovoltaic cells may be compared with each other to specify a column with a defect.

In this embodiment, the transparent electrode 12 is formed contacting the substrate 10 except the area of the slit S2 so that the transparent electrode 12 is also in contact with the substrate 10 between the side wall of the slit S2 and the wide wall of the slit S5. This makes adhesive strength stronger, compared to a structure according to a conventional method, in which the photovoltaic layer 14 is in contact with the substrate 10 in the area between the side wall of the slit S2 and the side wall of the slit S5. Therefore, even with a shape in which the slit S2 is formed by laser processing with a concave and a convex resultantly formed on the side wall of the slit S2, it is possible to prevent a film from being removed in spite of stress applied due to a heat cycle caused in the manufacturing process or when the photovoltaic device 100 is installed outside. Moreover, it is possible to prevent reduction of an effective power generation area due to a film being removed and also drop of power generation efficiency and thus reduction of output of the photovoltaic device 100 due to water invading between the transparent electrode 12 and the substrate 10.

Note that a process of removing an external edge portion of the photovoltaic device 200 may be provided after S44. Also, a step of forming a back sheet or a resin layer for protecting the surface of the photovoltaic device 200 may be provided after S40. A back sheet or a resin layer serves as a protection layer of the photovoltaic device 200.

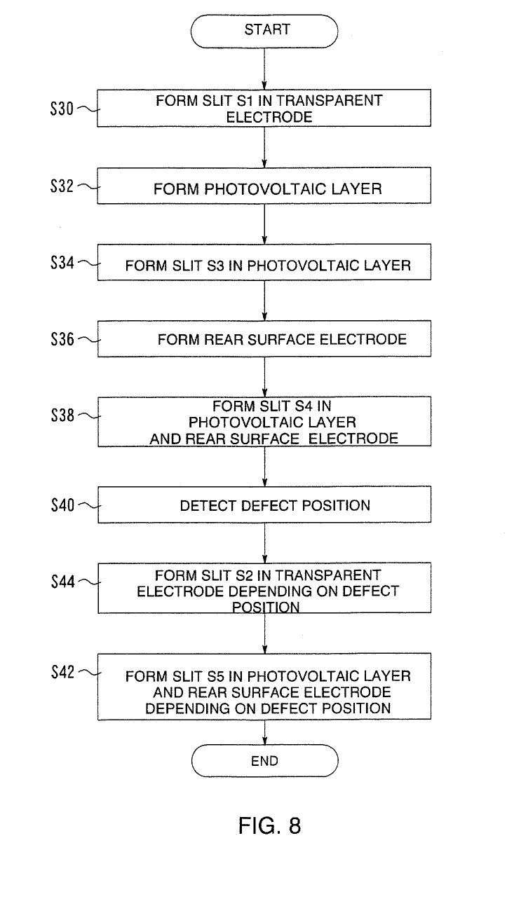

As shown in the flowchart of FIGS. 8, S42 and S44 may be performed in a reversed order. In this case, the slit S2 is formed by laser processing to divide the transparent electrode 12 formed on the transparent substrate 10 before the slit S5 is formed in laser processing at a position overlapping the slit S2 to divide the photovoltaic layer 14 and the rear surface electrode 16.

In the above, when the slit S2 is formed by laser processing, the area irradiated by the laser is heated and the photovoltaic layer 14 may be melted to be crystallized, causing a lower resistance portion. As a current flows more easily in a low resistance portion than in other areas in the photovoltaic layer 14, it is possible to cause a short-circuit via the low resistance portion between the transparent electrode 10 and the rear surface electrode 16 and, in a structure with an intermediate layer formed, between the transparent electrode 10 and the rear surface electrode 16 and between the intermediate layers, and thus to lower output from the photovoltaic cell. In this embodiment, with the slit S5 formed, the side walls of the rear surface electrode 16 and the photovoltaic layer 14, which come about because of the slit S2, are eliminated. Thus, a low resistance portion caused in a part of the photovoltaic layer 14 when making the slit S2, corresponding to the side wall of the slit S2, can be eliminated. Accordingly, it is possible to prevent occurrence of a short-circuit via a low resistance portion, and thus to better prevent drop in output from the photovoltaic device 100.

As described above, the slits S1, S3, and S4 are formed for serially connecting the adjacent photovoltaic cells, and the slits S2 and S5 are formed for arranging the groups of serially connected photovoltaic cells in parallel. With the above, the photovoltaic cells adjacent to each other along the direction of the slit S1 are electrically separated, and accordingly, a structure in which photovoltaic cell groups each including a plurality of serially connected photovoltaic cells are arranged in parallel results. The groups of photovoltaic cells are finally connected in parallel, whereby the photovoltaic device 200 is formed.

In this embodiment, in particular, the photovoltaic cells are divided in parallel such that the width of the column of serially connected photovoltaic cells including a photovoltaic cell with a defect is resultantly narrower than that without a defect. Accordingly, it is possible to define the range (hatched in FIGS. 6 and 7) subjected to influence of a defect, smaller than that which is defined according to a conventional method, so that the power generation efficiency of the photovoltaic device 200 can be improved.

Note that although a YAG laser with a wavelength 532 nm (second harmonic wave) is used in forming the slit S5 in the above, any laser device having energy large enough to remove the photovoltaic layer 14 is usable. Specifically, for the photovoltaic layer 14 made of amorphous silicon, a laser device with a wavelength between 400 nm and 600 nm is usable, and for the photovoltaic layer 14 made of microcrystal silicon, a laser device with a wavelength between 60 nm and 80 nm is usable.

Further, although a YAG laser (basic wave) with a wavelength 1064 nm is used in forming the slit S2 in the above, any laser device having energy large enough to remove the transparent electrode 12 is usable. Specifically, for the transparent electrode 12 made of transparent electrically conductive oxide (ICC)), ultraviolet light having a wavelength of 400 nm or smaller or an infrared light having a wavelength of 800 nm or larger is usable. Note that to remove a transparent electrode, using infrared light having a wavelength 400 nm or smaller, preferably, the laser beam is irradiated from the transparent electrode 12 side as the material of the substrate 10, such as glass or resin, also absorbs light. Further, when using far-infrared light having a wavelength of 8000 nm or larger in infrared light having a wavelength of 800 nm or larger, preferably, the laser beam is irradiated from the transparent electrode 12 side as the material of the substrate 10, such as glass, also absorbs light.

Note that the above described embodiment is merely one example. For a tandem structure including a plurality of amorphous silicon (a-Si) photovoltaic layers and microcrystal (μc-Si) photovoltaic layers, the structure may include an intermediate layer. In this case, transparent electrically conductive oxide (TCO) formed by doping tin (Sn), antimony (Sb), fluorine (F), aluminum (Al), and so forth into stannous oxide (SnO₂), zinc oxide (ZnO), indium tin oxide (ITO), or the like, may be used as an intermediate layer.

What is claimed is:

1. A method for manufacturing a photovoltaic device, comprising:
a first step of serially connecting a plurality of photovoltaic elements ,where sequentially stacked a first electrode, a photovoltaic layer, and second electrode;
a second step of measuring characteristics of the photovoltaic element; and
a third step of removing, according to a result of measurement, the first electrode, the photovoltaic layer, and the second electrode along a direction in which the photovoltaic elements are serially connected to thereby divide the plurality of photovoltaic elements serially connected into a plurality of regions.

2. The method for manufacturing a photovoltaic device according to claim. 1, wherein the third step is a step of dividing the plurality of photovoltaic elements serially connected into a plurality of regions having different areas.

3. The method for manufacturing a photovoltaic device according to claim 1, wherein
the second step is a step of measuring a position of a defect caused in the photovoltaic element, and
the third step is a step of dividing the plurality of photovoltaic elements serially connected into a plurality of regions to electrically separate the defect from other regions, depending on the position of the defect.

4. The method for manufacturing a photovoltaic device according to claim 1, wherein
the second step is a step of measuring electric characteristics of the photovoltaic element, and
the third step of a step of dividing the plurality of photovoltaic elements serially connected into a plurality of regions, depending on a result of measurement of the electric characteristics.

5. The method for manufacturing a photovoltaic device according to claim 1, wherein
the third step includes
a step of removing the photovoltaic layer and the second electrode by an amount corresponding to a first width, and
a step of removing the first electrode by an amount corresponding to a second width equal to or smaller than the first width, in a region overlapping a region where the photovoltaic layer and the second electrode are removed.

6. The method for manufacturing a photovoltaic device according to claim 1, wherein
the third step includes
a step of removing the first electrode, the photovoltaic layer, and the second electrode by an amount corresponding to a second width, and
a step of removing the photovoltaic layer and the second electrode by an amount corresponding to a first width equal to or larger than the second width in a region overlapping a region where the first electrode, the photovoltaic layer, and the second electrode are removed.

7. A photovoltaic device in which a plurality of photovoltaic elements, where a first electrode, a photovoltaic layer, and a second electrode are sequentially stacked, are serially connected, wherein the first electrode, the photovoltaic layer, and the second electrode are removed along a direction in which the photovoltaic elements are serially connected, to thereby divide the plurality of photovoltaic elements serially connected into a plurality of regions having different areas.

8. A method of manufacturing a photovoltaic device, comprising:
a first step of sequentially stacking a first electrode, a photovoltaic layer, and a second electrode to thereby form a photovoltaic element;
a second step of removing the second electrode and the photovoltaic layer to thereby form a first slit; and
a third step of removing the first electrode in a region overlapping the first slit to thereby form a second slit to thereby divide the photovoltaic element into a plurality of regions.

9. The method of manufacturing a photovoltaic device according to claim 8, wherein
the second step is a step of removing the photovoltaic layer and the second electrode by an amount corresponding to a first width, and
the third step is a step of removing the first electrode by an amount corresponding to a second width smaller than the first width.

10. A method of manufacturing a photovoltaic device, comprising:
a first step of sequentially stacking a first electrode, a photovoltaic layer, and a second electrode to thereby form a photovoltaic element;
a second step of removing the first electrode, the photovoltaic layer, and the second electrode to thereby form a third slit to thereby divide the photovoltaic element into a plurality of regions; and
a third step of removing the second electrode and the photovoltaic layer in a region including the third slit to thereby form a fourth slit.

11. The method of manufacturing a photovoltaic device according to claim 10, wherein
the second step is a step of removing the first electrode, the photovoltaic layer, and the second electrode by an amount corresponding to a third width, and
the third step is a step of removing the photovoltaic layer and the second electrode by an amount corresponding to a fourth width larger than the third width.

12. The method of manufacturing a photovoltaic device according to claim 8, wherein the photovoltaic element formed at the first step is formed on a substrate having an insulating surface.

13. The method of manufacturing a photovoltaic device according to claim 10, wherein the photovoltaic element formed at the first step is formed on a substrate having an insulating surface.

14. The method of manufacturing a photovoltaic device according to claim 8, wherein the first electrode, the photovoltaic layer, and the second electrode are removed using a laser at the second step and the third step.

15. The method of manufacturing a photovoltaic device according to claim 10, wherein the first electrode, the photovoltaic layer, and the second electrode are removed using a laser at the second step and the third step.
